(19) United States
(12) Patent Application Publication
(10) Pub. No.: US 2026/0063675 A1
(43) Pub. Date: Mar. 5, 2026

(54) ELECTRICAL POWER CONTROL DEVICES AND RELATED METHODS

(71) Applicant: ABB SCHWEIZ AG, Baden (CH)

(72) Inventor: Abhinav Patni, Raleigh, NC (US)

(21) Appl. No.: 18/822,993

(22) Filed: Sep. 3, 2024

(51) Int. Cl. G01R 15/14; G01R 21/06; H05K 1/18

(52) U.S. Cl. CPC G01R 15/14; G01R 21/06; H05K 1/18; H05K 2201/10053; H05K 2201/10151; H05K 2201/10189

(57) ABSTRACT

Electrical power control devices may include a main circuit board assembly that includes a data collection and control module and one or more auxiliary electrical connectors. One or more auxiliary circuit board assemblies may be respectively connected to the one or more auxiliary electrical connectors. Each of the auxiliary circuit board assemblies may include an auxiliary relay configured to open or close an auxiliary power line for powering an auxiliary device and an auxiliary power sensor configured to sense at least one electrical characteristic (e.g., current, voltage, etc.) of the auxiliary power line. Various other related systems and methods are also disclosed.

### BACKGROUND

The increasing popularity of electric vehicles (EVs) or other auxiliary electrical devices has led to a rise in energy use in homes. This higher power usage, including from homes with EV chargers, can benefit from electrical power data monitoring. Such monitoring systems may be helpful in comprehending energy use patterns and improving overall consumption. The data obtained can offer homeowners useful details about their energy use, allowing them to better control power and balance between everyday electricity needs and auxiliary demands (e.g., EV charging demands). Higher energy bills can often result from increased electrical loads, making power data monitoring a helpful consideration for homeowners who have auxiliary electrical needs. These monitoring systems can also support utility companies in handling grid load more efficiently, helping avoid power outages or fluctuations that could disrupt service.

### BRIEF SUMMARY

In some aspects, the techniques described herein relate to an electrical power control device, including: a main circuit board assembly, including: a data collection and control module; and one or more auxiliary electrical connectors; and one or more auxiliary circuit board assemblies respectively connected to the one or more auxiliary electrical connectors, each of the one or more auxiliary circuit board assemblies including: an auxiliary relay configured to open or close an auxiliary power line for powering an auxiliary device; and an auxiliary power sensor configured to sense at least one electrical characteristic of the auxiliary power line.

In some aspects, the techniques described herein relate to a device, wherein the one or more auxiliary electrical connectors includes between two and twelve electrical connectors.

In some aspects, the techniques described herein relate to a device, wherein the one or more auxiliary electrical connectors includes between two and six auxiliary electrical connectors.

In some aspects, the techniques described herein relate to a device, wherein the data collection and control module of the main circuit board assembly includes one or more microprocessors.

In some aspects, the techniques described herein relate to a device, wherein the one or more microprocessors is operably connected to, through the one or more auxiliary electrical connectors, the auxiliary power sensor of each of the one or more auxiliary circuit board assemblies to receive information indicative of the at least one electrical characteristic from the auxiliary power sensor.

In some aspects, the techniques described herein relate to a device, wherein the one or more microprocessors is operably connected to, through the one or more auxiliary electrical connectors, the auxiliary relay of each of the one or more auxiliary circuit board assemblies to control an open or closed state of the auxiliary relay.

In some aspects, the techniques described herein relate to a device, wherein each of the one or more auxiliary circuit board assemblies further includes an analog-to-digital converter to convert analog data from the auxiliary power sensor to digital data.

In some aspects, the techniques described herein relate to a device, wherein the one or more auxiliary electrical connectors includes one or more auxiliary ribbon cable connectors.

In some aspects, the techniques described herein relate to a device, wherein the main circuit board assembly further includes a main power sensor configured to sense at least one electrical power characteristic of a main power line for transmitting power to a disconnect panel.

In some aspects, the techniques described herein relate to a device, wherein each of the auxiliary power sensor and the main power sensor includes an electrical current sensor.

In some aspects, the techniques described herein relate to a device, wherein the data collection and control module includes a communication module for communicating information based on the at least one electrical power characteristic of the auxiliary power line to a user device.

In some aspects, the techniques described herein relate to a device, wherein the auxiliary device includes one or more of: an electric vehicle charging station; an electric vehicle; a pump; an air conditioning unit; a heater; or a refrigerator.

In some aspects, the techniques described herein relate to an electrical power monitoring device, including: a main circuit board assembly, including: one or more auxiliary electrical connectors; and one or more auxiliary circuit board assemblies respectively connected to the one or more auxiliary electrical connectors, each of the one or more auxiliary circuit board assemblies including: an auxiliary relay configured to open or close an auxiliary power line for powering an auxiliary device; an auxiliary power sensor configured to sense at least one electrical power characteristic of the auxiliary power line; and an auxiliary data collection and control module operably connected to the auxiliary power sensor for collecting and processing data from the auxiliary power sensor.

In some aspects, the techniques described herein relate to a device, wherein the one or more auxiliary electrical connectors includes two or more auxiliary electrical connectors.

In some aspects, the techniques described herein relate to a device, wherein the main circuit board assembly further includes a main power sensor configured to sense at least one electrical power characteristic of a main power line for transmission of power to a disconnect panel.

In some aspects, the techniques described herein relate to a device, wherein the main circuit board assembly further includes a main data collection and control module operably connected to the main power sensor for collecting and processing data from the main power sensor.

In some aspects, the techniques described herein relate to a device, wherein each auxiliary data collection and control module includes an auxiliary microprocessor.

In some aspects, the techniques described herein relate to a device, wherein each auxiliary power sensor includes an electrical current sensor.

In some aspects, the techniques described herein relate to a method of forming an electrical monitoring device, the method including: operably coupling an auxiliary relay and an auxiliary sensor to an auxiliary circuit board to form an auxiliary circuit board assembly, the auxiliary relay configured to open or close an auxiliary power line for powering an auxiliary device and the auxiliary sensor configured to sense at least one electrical characteristic of the auxiliary power line; operably coupling the auxiliary circuit board assembly to an auxiliary electrical connector of two or more auxiliary electrical connectors of a main circuit board assembly; and operably coupling the auxiliary sensor to a data collection and control module.

In some aspects, the techniques described herein relate to a method, wherein operably coupling the auxiliary sensor to the data collection and control module includes at least one of: operably coupling the auxiliary sensor to a main microprocessor of the main circuit board assembly; or operably coupling the auxiliary sensor to an auxiliary microprocessor of the auxiliary circuit board assembly.

### BRIEF DESCRIPTION OF THE DRAWINGS

FIG. 1 is a schematic view of a power supply system that includes an electrical monitoring device, according to at least one embodiment of the present disclosure.

FIG. 2 is a schematic view of a power supply system that includes an electrical monitoring device, according to at least one additional embodiment of the present disclosure.

FIG. 3 is a schematic diagram of a power supply system that is connected to multiple auxiliary devices, according to at least one embodiment of the present disclosure.

FIG. 4 is a schematic diagram of a power supply system that is connected to multiple auxiliary devices, according to at least one additional embodiment of the present disclosure.

FIG. 5 is a schematic diagram of an electrical monitoring device, according to at least one embodiment of the present disclosure, according to at least one embodiment of the present disclosure.

FIG. 6 is a flow diagram illustrating a method of forming an electrical monitoring device, according to at least one embodiment of the present disclosure.

Throughout the drawings, identical reference characters and descriptions indicate similar, but not necessarily identical, elements. While the example embodiments described herein are susceptible to various modifications and alternative forms, specific embodiments have been shown by way of example in the drawings and will be described in detail herein. However, the example embodiments described herein are not intended to be limited to the particular forms disclosed. Rather, the present disclosure covers all modifications, equivalents, and alternatives falling within the scope of the appended claims.

### DETAILED DESCRIPTION OF EXAMPLE EMBODIMENTS

The present disclosure provides detailed descriptions of electrical power control devices. As will be explained in greater detail below, embodiments of the present disclosure may include a main circuit board assembly that includes a data collection and control module and one or more auxiliary electrical connectors. One or more auxiliary circuit board assemblies may be respectively connected to the one or more auxiliary electrical connectors. Each of the auxiliary circuit board assemblies may include an auxiliary relay configured to open or close an auxiliary power line for powering an auxiliary device and an auxiliary power sensor configured to sense at least one electrical characteristic (e.g., current, voltage, etc.) of the auxiliary power line. In some examples, such devices may be capable of monitoring the electrical characteristic(s) and automatically reacting to power demand by controlling the auxiliary relay(s).

Features from any of the embodiments described herein may be used in combination with one another in accordance with the general principles described herein. These and other embodiments, features, and advantages will be more fully understood upon reading the following detailed description in conjunction with the accompanying drawings and claims.

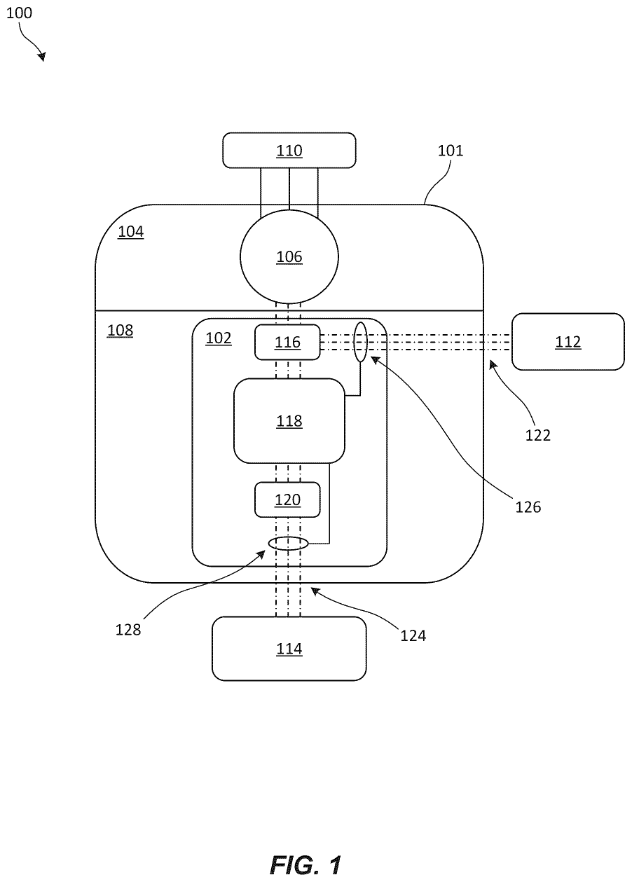

FIG. 1 is a schematic view of a power supply system 100 that includes an electrical monitoring device 102, according to at least one embodiment of the present disclosure. The power supply system 100 may be in the form of an expanded meter socket 101 that includes the electrical monitoring device 102.

For example, the power supply system 100 may include a meter socket section 104 that houses a power meter 106 and a power monitoring section 108 that houses the electrical monitoring device 102. In some embodiments, the meter socket section 104 may be locked or otherwise access-limited (e.g., for access only by personnel authorized by a power company), such as to inhibit tampering and/or theft of electrical power and for safety. The power monitoring section 108 may be accessible by a user and/or electrician (e.g., without authorization by a power company), such as for installation, maintenance, modification, etc.

The power supply system 100 may be connected at an input side to a utility grid 110 for providing power to the power supply system 100, through the electrical monitoring device 102, and ultimately to a user's electrical systems, such as to a disconnect panel 112 (e.g., a residential breaker panel, a commercial breaker panel, a fuse box, a fusible switch box, a protective relay panel, etc.) and/or to an auxiliary device 114. In the example shown in FIG. 1, the utility grid 110 may provide a single phase (e.g., three-wire) alternating current (AC) power supply including at least a hot wire and a neutral wire. In additional examples, the utility grid 110 may be a two-wire AC power supply or a four-wire AC power supply. The AC power supply from the utility grid 110 may be a single-phase (e.g., split-phase) AC power supply or a three-phase AC power supply.

Power from the utility grid 110 may pass through the power meter 106 for measuring total electrical power usage through the disconnect panel 112 and the auxiliary device 114. An output side of the power meter 106 may be operably connected to a power input of the electrical monitoring device 102, such as via suitable conductors (e.g., cables, wires, traces, etc.).

The electrical monitoring device 102 may include an input disconnect 116, a data collection and control module 118, and an auxiliary disconnect 120. A main power connection 122 of the electrical monitoring device 102 may be capable of transmitting electrical power from the electrical monitoring device 102 to the disconnect panel 112. An auxiliary power connection 124 of the electrical monitoring device 102 may be capable of transmitting electrical power from the electrical monitoring device 102 to and/or from the auxiliary device 114.

The input disconnect 116 may be positioned between the power meter 106 and the data collection and control module 118 and between the power meter 106 and the disconnect panel 112. In some embodiments, the input disconnect 116 may be rated with a sufficiently high amperage to supply full power to both the disconnect panel 112 and the auxiliary device 114. In other words, the current rating of the input disconnect 116 may be at least as high as the combination of the disconnect panel 112 rating and of the auxiliary device 114 rating, such as to reduce instances of the input disconnect 116 inadvertently opening and halting service to both the disconnect panel 112 and to the auxiliary device 114.

The auxiliary disconnect 120 may be positioned between the data collection and control module 118 and the auxiliary device 114. The auxiliary disconnect 120 may be configured to interrupt service to or from the auxiliary device 114 for installation or maintenance, in case of a fault (e.g., short-circuit) in the auxiliary device 114, for installation or maintenance of the data collection and control module 118, etc.

As will be explained further below, the data collection and control module 118 may be configured to sense at least one first electrical characteristic of the main power connection 122 and at least one second electrical characteristic of the auxiliary power connection 124. For example, the electrical monitoring device 102 may include at least one main sensor 126 for sensing the first electrical characteristic of the main power connection 122 and at least one auxiliary sensor 128 for sensing the second electrical characteristic of the auxiliary power connection 124. By way of example and not limitation, each of the at least one main sensor 126 and the at least one auxiliary sensor 128 may be in the form of an inductive sensor, a current shunt sensor, a Hall effect-based sensor, a fluxgate sensor, and/or a Rogowski principle-based sensor (e.g., a Rogowski coil sensor).

In some examples, relational terms, such as “first,” “second,” “main,” “auxiliary,” etc., may be used for clarity and convenience in understanding the disclosure and accompanying drawings and do not connote or depend on any specific preference, orientation, or order, except where the context clearly indicates otherwise.

The data collection and control module 118 may be in the form of a printed circuit board (PCB) that includes at least an analog-to-digital converter for processing signals from the at least one main sensor 126 and at least one auxiliary sensor 128. The data collection and control module 118 may also include a control module for controlling power to the auxiliary device 114 and/or a communication module for communicating information based on the signals to a user device or other recipient. One or more of these components of the data collection and control module 118 may be implemented via one or more microprocessors, signal processing components, transistors, transceivers, etc.

In some embodiments, the first electrical characteristic and the second electrical characteristic may include current and/or voltage, and/or a characteristic derived from current and/or voltage (e.g., power). The data collection and control module 118 may also be configured to communicate the first and second electrical characteristic, or information based on the first and second electrical characteristic, to a user device or other recipient. For example, the main sensor 126 may be or include a first current sensor for sensing an electrical current in the main power connection 122 and the auxiliary sensor 128 may be or include a second current sensor for sensing an electrical current in the auxiliary power connection 124. Responsive to levels of the first and second electrical characteristic and/or to a command from the user device or other recipient, the data collection and control module 118 may disconnect at least some power to the auxiliary device 114 and/or reconnect power to the auxiliary device 114.

The auxiliary device 114 may be one or more devices that use electrical power. Examples of the auxiliary device 114 include an electric vehicle (EV) charging station, an EV, a pump, an air conditioning unit, a heater, a refrigerator. Other devices that draw electrical power may also be considered auxiliary devices 114. In additional embodiments of the present disclosure, the auxiliary device 114 may generate electricity, and the auxiliary power connection 124 may operate as an input, such as for providing electrical power to the disconnect panel 112. For example, the auxiliary device 114 may be or include a wind turbine, a water turbine, a thermal power generator, a gas generator, a solar panel, etc. In some embodiments, an EV may include sufficient onboard circuitry and components to charge and/or discharge by connecting to a standard (e.g., 110V, 115V, 120V, 208V, 220V, 230V, 240V, etc.) electrical outlet without a separate EV charging station. Examples of such EVs may function as a current load or as a current source. Accordingly, the at least one auxiliary sensor 128 can, in some embodiments, be used to obtain power data regardless of the direction that electrical current flows in the auxiliary power connection 124.

FIG. 1 illustrates a single auxiliary device 114. However, the present disclosure is not so limited. In additional examples, the auxiliary device 114 may represent multiple auxiliary devices 114 connected to the electrical monitoring device 102.

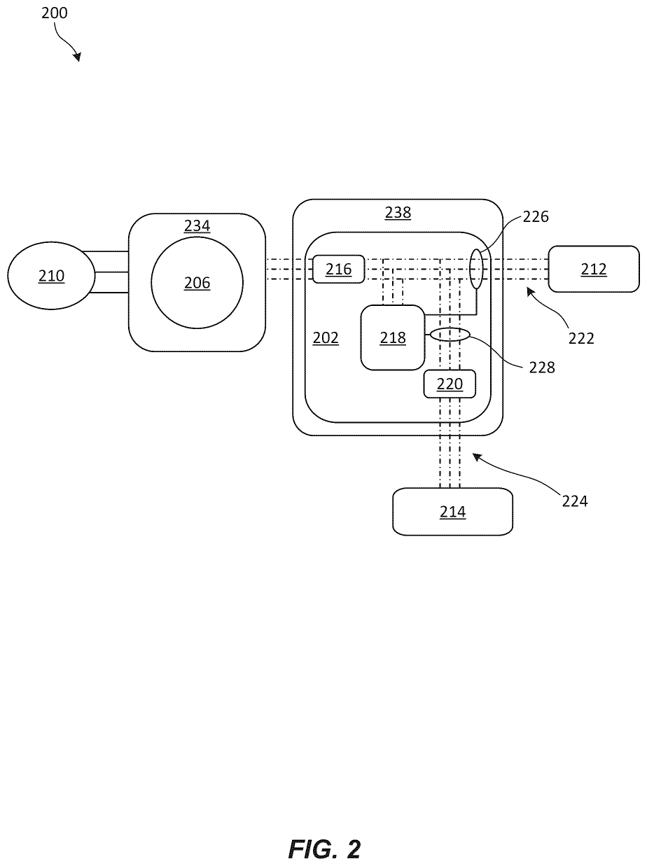

FIG. 2 is a schematic view of a power supply system 200 that includes an electrical monitoring device 202, according to at least one additional embodiment of the present disclosure.

In some respects, the power supply system 200 of FIG. 2 may be similar to the power supply system 100 illustrated in FIG. 1. For example, the power supply system 200 of FIG. 2 may include a power meter 206 that receives electrical power from a utility grid 210, a disconnect panel 212 (e.g., a residential breaker panel, a commercial breaker panel, a fuse box, a fusible switch box, a protective relay panel, etc.) and an auxiliary device 214, and the electrical monitoring device 202 that is configured to monitor electrical characteristics of a main power connection 222 to the disconnect panel 212 and of an auxiliary power connection 224 to the auxiliary device 214, such as via a main sensor 226 and/or an auxiliary sensor 228. The electrical monitoring device 202 may include an input disconnect 216, a data collection and control module 218, and an auxiliary disconnect 220.

Referring to FIG. 2, the power supply system 200 may include a meter socket 234 containing the power meter 206 that is physically separate from a housing 238 that contains the electrical monitoring device 202. In some examples, the housing 238 and electrical monitoring device 202 therein may be mounted adjacent to (e.g., along a same wall as) the meter socket 234. In additional examples, the housing 238 and electrical monitoring device 202 may be mounted remotely from the meter socket 234, such as adjacent to the auxiliary device 214 or adjacent to the disconnect panel 212.

Accordingly, referring to FIGS. 1 and 2, electrical monitoring devices 102, 202 of the present disclosure may be implemented as part of an expanded meter socket 101 or via a housing 238 that is separate from a meter socket 234. The functional components of the electrical monitoring devices 102, 202 may be the same or similar in either case.

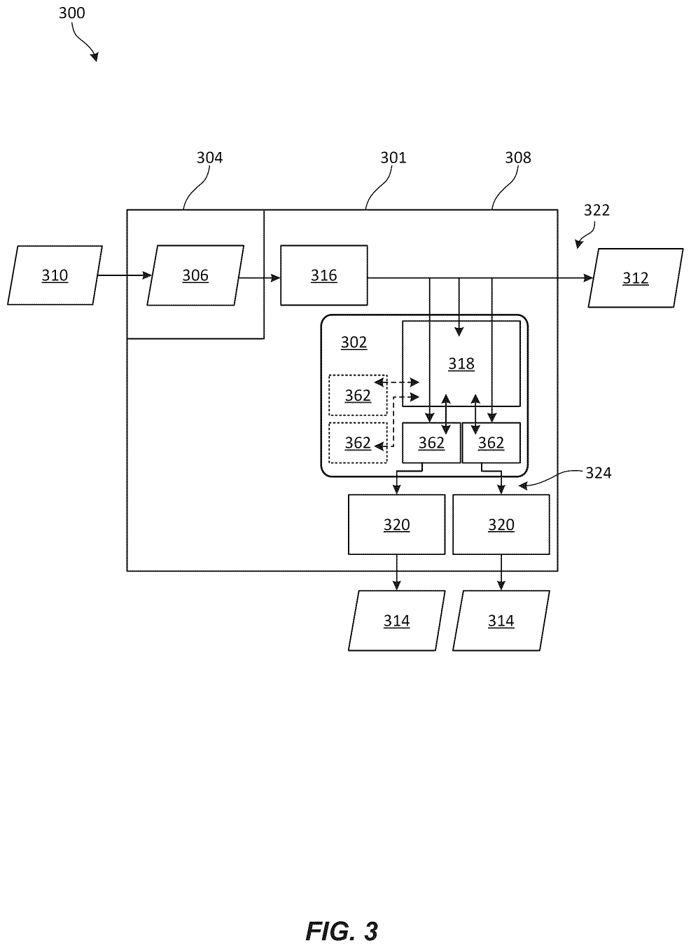

FIG. 3 is a schematic diagram of a power supply system 300 that is connected to multiple auxiliary devices 314, according to at least one embodiment of the present disclosure.

In some respects, the power supply system 300 may be similar to the power supply system 100 of FIG. 1. For example, the power supply system 300 may include an expanded meter socket 301, which may include a meter socket section 304 and a power monitoring section 308 in a common housing. An electrical monitoring device 302 may be positioned in the power monitoring section 308, which may be accessible by a user and/or electrician. A power meter 306 may be positioned in the meter socket section 304, which may be locked or otherwise access-limited. At an input side, the power supply system 300 may be connected to a utility grid 310. At an output side, the power supply system 300 may be connected to a disconnect panel 312 (e.g., a residential breaker panel, a commercial breaker panel, a fuse box, a fusible switch box, a protective relay panel, etc.) and to one or more auxiliary devices 314.

A main disconnect 316 in the power monitoring section 308 may be configured to shut off and restore power to both the disconnect panel 312 and the multiple auxiliary devices 314. One or more auxiliary disconnects 320 may be configured to shut off and restore power to the multiple auxiliary devices 314. In the example shown in FIG. 3, a separate auxiliary disconnect 320 is illustrated for each auxiliary device 314 of the multiple auxiliary devices.

The electrical monitoring device 302 may include a data collection and control module 318 configured to collect data corresponding to at least one main electrical characteristic (e.g., current, voltage, etc.) of a main power connection 322 to the disconnect panel 312 and data corresponding to at least one auxiliary electrical characteristic of each of the auxiliary power connections 324 to the multiple auxiliary devices 314.

The electrical monitoring device 302 may include multiple (e.g., two) auxiliary electrical connections 362 for connecting to the multiple auxiliary devices 314, respectively. In addition, the electrical monitoring device 302 may include more auxiliary electrical connections 362 (shown in dashed lines in FIG. 3) for connecting to additional auxiliary devices 314. Thus, the power supply system 300 may be modular, including slots for monitoring and controlling one or more auxiliary devices 314 in a variety of applications.

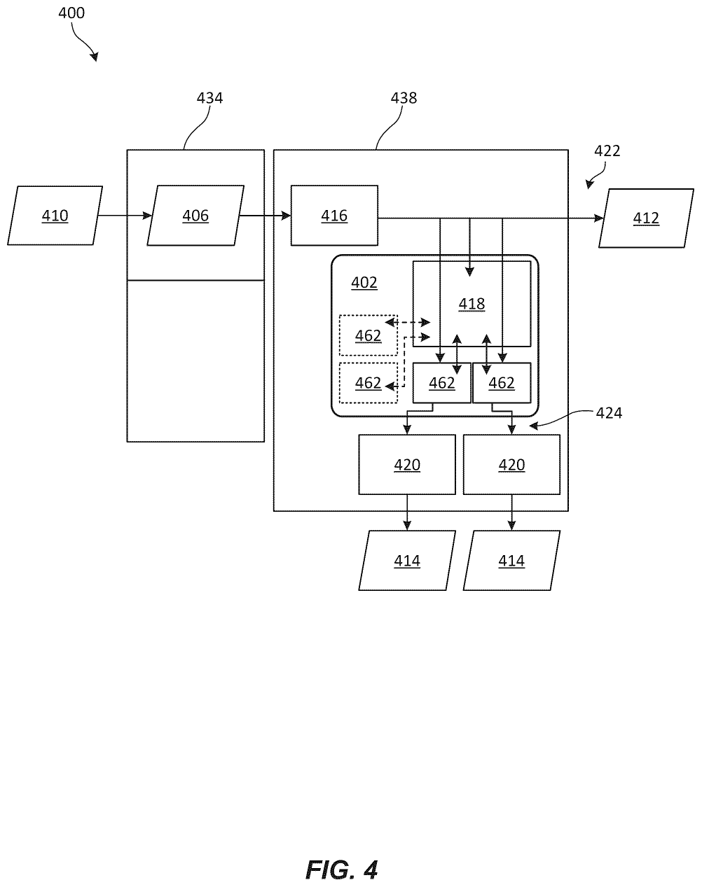

FIG. 4 is a schematic diagram of a power supply system 400 that is connected to multiple auxiliary devices 414, according to at least one additional embodiment of the present disclosure.

In some respects, the power supply system 400 of FIG. 4 is similar to the power supply system 200 of FIG. 2. For example, the power supply system 400 may include a housing 438 that contains an electrical monitoring device 402 and a meter socket 434 that contains a power meter 406 that receives electrical power from a utility grid 410. The electrical monitoring device 402 may be configured to monitor electrical characteristics (e.g., current, voltage, etc.) of a main power connection 422 to a disconnect panel 412 and of auxiliary power connections 424 to multiple auxiliary devices 414. The housing 438 may also contain an input disconnect 416 and multiple auxiliary disconnects 420 corresponding to the multiple auxiliary devices 414.

The electrical monitoring device 402 may include a data collection and control module 418 that may collect data corresponding to the electrical characteristics of the main power connection 422 and of the auxiliary power connections 424. The data collection and control module 418 may also be configured to control the flow of electrical power to the multiple auxiliary devices 414, such as with multiple relays corresponding to the multiple auxiliary devices 414. The electrical monitoring device 402 may include multiple auxiliary electrical connections 462 for respectively connecting to at least the multiple auxiliary devices 414. Optionally, additional auxiliary electrical connections 462 (shown in dashed lines in FIG. 4) may be included in the electrical monitoring device 402 to provide an option for connecting one or more additional auxiliary devices 414 to the electrical monitoring device 402.

As illustrated in FIG. 4, the housing 438 may be physically separate from the meter socket 434. In some examples, the housing 438 may be mounted adjacent to (e.g., along a same wall as) the meter socket 434. In additional examples, the housing 438 may be mounted remotely from the meter socket 434, such as adjacent to the one or more of the multiple auxiliary devices 414 or adjacent to the disconnect panel 412.

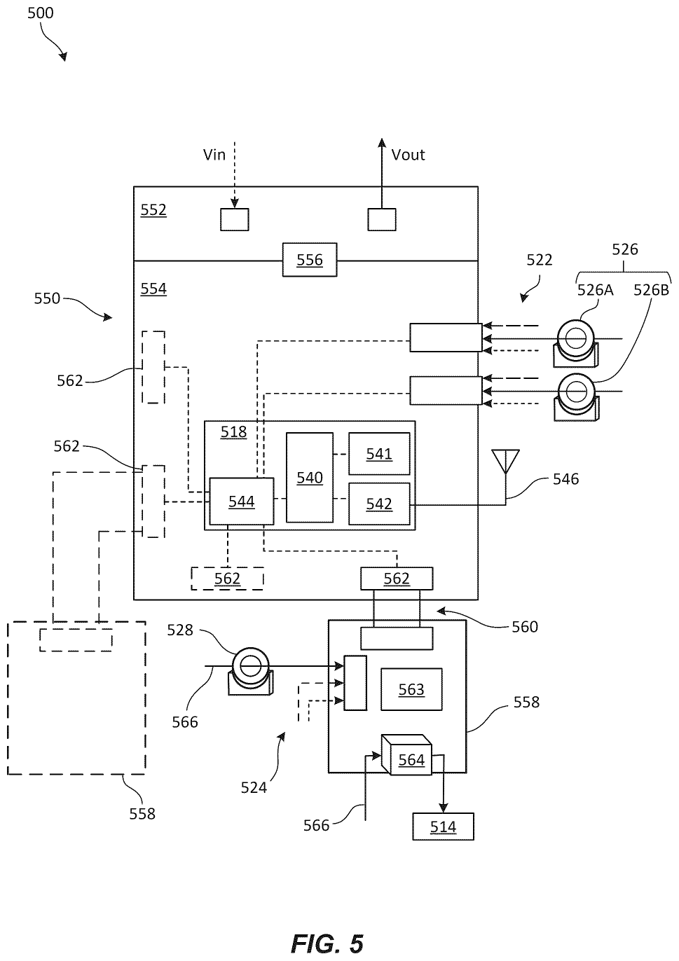

FIG. 5 is a schematic diagram of an electrical monitoring device 500, according to at least one embodiment of the present disclosure, according to at least one embodiment of the present disclosure. In some examples, the electrical monitoring device 500 may be implemented or employed as any of the electrical monitoring devices 102, 202, 302, 402 described above.

The electrical monitoring device 500 may include a data collection and control module 518, which may be implemented in one or more microcontrollers and/or separate modules. The data collection and control module 518 may include a data collection module 540 and a control module 541. In some embodiments, the data collection and control module 518 may also include a communication module 542. The data collection module 540 may receive data from at least one main sensor 526 (e.g., a first main sensor 526A and a second main sensor 526B) coupled to a main power connection 522. In the example illustrated in FIG. 5, the main power connection 522 may be configured for split-phase power. The first main sensor 526A may be coupled to a hot wire associated with a first AC phase and the second main sensor 526B may be coupled to a hot wire associated with a second AC phase. In additional embodiments, a single main sensor 526 or more than two main sensors 526 may be employed. The first main sensor 526A and the second main sensor 526B may be configured to sense one or more electrical characteristics (e.g., current, voltage) of the main power connection 522.

The data collection module 540 may also receive data from at least one auxiliary sensor 528. Only one auxiliary sensor 528 is illustrated in FIG. 5. However, the present disclosure is not so limited. In additional embodiments, multiple auxiliary sensors 528 may be used. The at least one auxiliary sensor 528 may be coupled to an auxiliary power connection 524, such as a hot wire 566 of the auxiliary power connection 524. The at least one auxiliary sensor 528 may be configured to sense at least one electrical characteristic (e.g., current, voltage) of the hot wire 566 of the auxiliary power connection 524.

The control module 541 may be configured to control the operation of the more respective auxiliary devices 514 based on data from the data collection module 540. For example, the control module 541 may send signals to one or more relays 564 to control whether electrical power is supplied to the more respective auxiliary devices 514.

The data collection and control module 518 may also include an analog-to-digital converter 544 for converting analog signals from the at least one main sensor 526 and from the at least one auxiliary sensor 528 to digital signals. The data collection module 540 may receive the digital signals from the analog-to-digital converter 544 and may pass information based on the digital signals to the communication module 542 for communication to a user device, such as via a wired connection or a wireless connection (e.g., via an antenna 546).

As illustrated in FIG. 5, in some examples of the present disclosure, the electrical monitoring device 500 may include one or more printed circuit boards (PCBs). For example, a main PCB 550 may support the data collection and control module 518. The main PCB 550 may include a high-voltage power plane 552 (e.g., 90 VAC power plane, a 120 VAC power plane, a 208 VAC power plane, a 240 VAC power plane, a 277 VAC power plane, etc.) that accepts electrical power from a utility grid. The main PCB 550 may also include a low-voltage power plane 554 (e.g., a 5 V power plane, a 3.3 V power plane, and a ground power plane). The high-voltage power plane 552 may be operably coupled to the low-voltage power plane 554 by a step-down converter 556, which may act as a convert the high voltage of the high-voltage power plane 552 to a low voltage for the low-voltage power plane 552. The low voltage of the low-voltage power plane 552 may be used by the data collection and control module 518.

In some examples, the electrical monitoring device 500 may also include an auxiliary PCB 558, which may be connected to the main PCB 550 via a connector 560 (e.g., a ribbon cable connector, a flat flexible cable (FFC) connector, a zero insertion force (ZIF) connector, a twisted pair cable connector, etc.) connected to an auxiliary electrical connector 562 of the main PCB 550. In some embodiments, the main PCB 550 may include two or more auxiliary electrical connectors 562, which may provide connections for connecting one, two, or more respective auxiliary devices 514 to the main PCB 550 through respective auxiliary PCBs 558.

By way of example, the auxiliary PCB 558 may include and/or support one or more of filters, the auxiliary sensor 528, an auxiliary microprocessor 563, filtering and signal conditioning circuits, etc. In some embodiments, the auxiliary relay 564 may be positioned on the auxiliary PCB 558. In additional embodiments, the auxiliary relay 564 may be positioned on the main PCB 550. In either case, the auxiliary relay 564 may be coupled to the hot wire 566 of the auxiliary power connection 524. The auxiliary relay 564 may be configured to open or close the hot wire 566 responsive to signals from the control module 541 and/or from the auxiliary microprocessor 563. In additional examples, one or more components of the auxiliary PCB 558 may be positioned on the main PCB 550 instead of or in addition to on an auxiliary PCB 558.

FIG. 5 illustrates a single auxiliary PCB 558 connected to the main PCB 550 for monitoring and controlling electrical power to a single auxiliary device 514. In additional examples, optionally, more than one auxiliary PCB 558 may be connected to the main PCB 550 for monitoring and controlling electrical power to more than one respective auxiliary device 514. One additional auxiliary PCB 558 is illustrated in dashed lines in FIG. 5, but any number of additional auxiliary PCBs 558 may be connected to a corresponding number of auxiliary electrical connectors 562 on the main PCB 550. For example, the main PCB 550 may include multiple auxiliary electrical connectors 562 for connecting up to the same number of auxiliary PCBs 558 and corresponding auxiliary devices 514. Accordingly, the electrical monitoring device 500 may be considered modular in the sense that one or more auxiliary devices 514 may be simultaneously connected, monitored, and controlled.

In FIG. 5, four auxiliary electrical connectors 562 are illustrated on the main PCB 550. However, the present disclosure is not so limited. In additional examples, a single auxiliary electrical connector 562 may be employed, or any number of auxiliary electrical connectors 562 that physically fit on the main PCB 550 may be employed. For example, one auxiliary electrical connector 562, two auxiliary electrical connectors 562, three auxiliary electrical connectors 562, four auxiliary electrical connectors 562, five auxiliary electrical connectors 562, six auxiliary electrical connectors 562, seven auxiliary electrical connectors 562, eight auxiliary electrical connectors 562, nine auxiliary electrical connectors 562, or ten auxiliary electrical connectors 562 may be employed for up to a corresponding number of auxiliary devices 514. In additional examples, more than ten auxiliary electrical connectors 562 may be included on the main PCB 550.

In some embodiments, the multiple auxiliary electrical connectors 562 may be positioned along one, two, three, or four of the peripheral edge regions of the main PCB 550. When a new auxiliary device 514 is to be connected to the system, a user or technician may connect another auxiliary PCB 558 to one of the open auxiliary electrical connectors 562, connect the new auxiliary device 514 to the auxiliary PCB 558, and couple a corresponding auxiliary sensor 528 to a hot wire 566 associated with the new auxiliary device 514. Much or all of the electrical power, processing, and communications associated with the new auxiliary device 514 and any previously connected auxiliary device(s) 514 may be handled by components of the main PCB 550. Accordingly, the modularity of the electrical monitoring device 500 may simplify and reduce cost of installation of one or more auxiliary devices 514 in a power supply system.

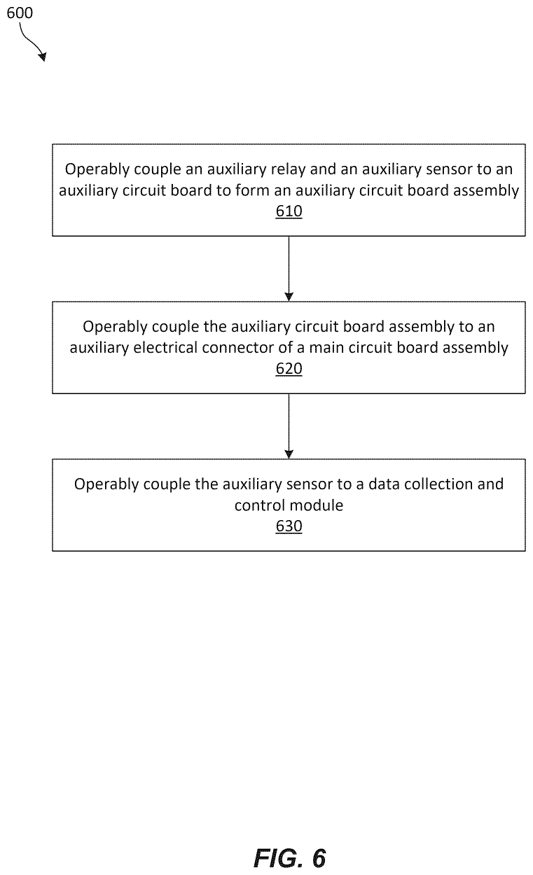

FIG. 6 is a flow diagram illustrating a method 600 of forming an electrical monitoring device, according to at least one embodiment of the present disclosure.

At operation 610, an auxiliary relay and an auxiliary sensor may be operably coupled to an auxiliary circuit board to form an auxiliary circuit board assembly. The auxiliary relay may be configured to open or close an auxiliary power line for powering an auxiliary device. The auxiliary sensor may be configured to sense at least one electrical characteristic (e.g., current, voltage, etc.) of the auxiliary power line.

At operation 620, the auxiliary circuit board assembly may be operably coupled to an auxiliary electrical connector of two or more auxiliary electrical connectors of a main circuit board assembly.

At operation 630, the auxiliary sensor may be operably coupled to a data collection and control module. The data collection and control module may be configured to collect data representative of the at least one electrical characteristic of the auxiliary power line. For example, the auxiliary sensor may be operably coupled to a main microprocessor of the main circuit board assembly. In another example, the auxiliary sensor may be operably coupled to an auxiliary microprocessor of the auxiliary circuit board assembly.

Accordingly, the present disclosure includes devices and methods for controlling and monitoring multiple auxiliary devices connected to a power supply. Some embodiments of such devices and methods may enable a system to automatically or manually power off and power on auxiliary devices, such as according to electrical demands of the system. Powering off one or more auxiliary devices using such devices or methods may reduce a risk of breakers or fuses automatically tripping during times of high demand and may facilitate reconnection of the one or more auxiliary devices when the high demand is reduced to a level sufficient for powering all devices on the system.

The following example embodiments are also included in the present disclosure.
Example 1. An electrical power control device, including: a main circuit board assembly, including: a data collection and control module; and one or more auxiliary electrical connectors; and one or more auxiliary circuit board assemblies respectively connected to the one or more auxiliary electrical connectors, each of the one or more auxiliary circuit board assemblies including: an auxiliary relay configured to open or close an auxiliary power line for powering an auxiliary device; and an auxiliary power sensor configured to sense at least one electrical characteristic of the auxiliary power line.
Example 2. The device of Example 1, wherein the one or more auxiliary electrical connectors includes between two and twelve electrical connectors.
Example 3. The device of Example 1 or Example 2, wherein the one or more auxiliary electrical connectors includes between two and six auxiliary electrical connectors.
Example 4. The device of any one of Examples 1 through 3, wherein the data collection and control module of the main circuit board assembly includes one or more microprocessors.
Example 5. The device of Example 4, wherein the one or more microprocessors is operably connected to, through the one or more auxiliary electrical connectors, the auxiliary power sensor of each of the one or more auxiliary circuit board assemblies to receive information indicative of the at least one electrical characteristic from the auxiliary power sensor.
Example 6. The device of Example 5, wherein the one or more microprocessors is operably connected to, through the one or more auxiliary electrical connectors, the auxiliary relay of each of the one or more auxiliary circuit board assemblies to control an open or closed state of the auxiliary relay.
Example 7. The device of any one of Examples 1 through 6, wherein each of the one or more auxiliary circuit board assemblies further includes an analog-to-digital converter to convert analog data from the auxiliary power sensor to digital data.
Example 8. The device of any one of Examples 1 through 7, wherein the one or more auxiliary electrical connectors includes one or more auxiliary ribbon cable connectors.
Example 9. The device of any one of Examples 1 through 8, wherein the main circuit board assembly further includes a main power sensor configured to sense at least one electrical power characteristic of a main power line for transmitting power to a disconnect panel.
Example 10. The device of Example 9, wherein each of the auxiliary power sensor and the main power sensor includes an electrical current sensor.
Example 11. The device of any one of Examples 1 through 10, wherein the data collection and control module includes a communication module for communicating information based on the at least one electrical power characteristic of the auxiliary power line to a user device.
Example 12. The device of any one of Examples 1 through 11, wherein the auxiliary device includes one or more of: an electric vehicle charging station; an electric vehicle; a pump; an air conditioning unit; a heater; or a refrigerator.
Example 13. An electrical power monitoring device, including: a main circuit board assembly, including: one or more auxiliary electrical connectors; and one or more auxiliary circuit board assemblies respectively connected to the one or more auxiliary electrical connectors, each of the one or more auxiliary circuit board assemblies including: an auxiliary relay configured to open or close an auxiliary power line for powering an auxiliary device; an auxiliary power sensor configured to sense at least one electrical power characteristic of the auxiliary power line; and an auxiliary data collection and control module operably connected to the auxiliary power sensor for collecting and processing data from the auxiliary power sensor.
Example 14. The device of Example 13, wherein the one or more auxiliary electrical connectors includes two or more auxiliary electrical connectors.
Example 15. The device of Example 13 or Example 14, wherein the main circuit board assembly further includes a main power sensor configured to sense at least one electrical power characteristic of a main power line for transmission of power to a disconnect panel.
Example 16. The device of Example 15, wherein the main circuit board assembly further includes a main data collection and control module operably connected to the main power sensor for collecting and processing data from the main power sensor.
Example 17. The device of any one of Examples 13 through 16, wherein each auxiliary data collection and control module includes an auxiliary microprocessor.
Example 18. The device of any one of Examples 13 through 17, wherein each auxiliary power sensor includes an electrical current sensor.
Example 19. A method of forming an electrical monitoring device, the method including: operably coupling an auxiliary relay and an auxiliary sensor to an auxiliary circuit board to form an auxiliary circuit board assembly, the auxiliary relay configured to open or close an auxiliary power line for powering an auxiliary device and the auxiliary sensor configured to sense at least one electrical characteristic of the auxiliary power line; operably coupling the auxiliary circuit board assembly to an auxiliary electrical connector of two or more auxiliary electrical connectors of a main circuit board assembly; and operably coupling the auxiliary sensor to a data collection and control module.
Example 20. The method of Example 19, wherein operably coupling the auxiliary sensor to the data collection and control module includes at least one of: operably coupling the auxiliary sensor to a main microprocessor of the main circuit board assembly; or operably coupling the auxiliary sensor to an auxiliary microprocessor of the auxiliary circuit board assembly.

While the foregoing disclosure sets forth various embodiments using specific block diagrams, flowcharts, and examples, each block diagram component, flowchart step, operation, and/or component described and/or illustrated herein may be implemented, individually and/or collectively, using a wide range of hardware, software, or firmware (or any combination thereof) configurations. In addition, any disclosure of components contained within other components should be considered example in nature since many other architectures can be implemented to achieve the same functionality.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various example methods described and/or illustrated herein may also omit one or more of the steps described or illustrated herein or include additional steps in addition to those disclosed.

The preceding description has been provided to enable others skilled in the art to best utilize various aspects of the example embodiments disclosed herein. This example description is not intended to be exhaustive or to be limited to any precise form disclosed. Many modifications and variations are possible without departing from the spirit and scope of the instant disclosure. The embodiments disclosed herein should be considered in all respects illustrative and not restrictive. Reference should be made to the appended claims and their equivalents in determining the scope of the instant disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. An electrical power control device, comprising:
a main circuit board assembly, comprising:
a data collection and control module; and
one or more auxiliary electrical connectors; and
one or more auxiliary circuit board assemblies respectively connected to the one or more auxiliary electrical connectors, each of the one or more auxiliary circuit board assemblies comprising:
an auxiliary relay configured to open or close an auxiliary power line for powering an auxiliary device; and
an auxiliary power sensor configured to sense at least one electrical characteristic of the auxiliary power line.

2. The device of claim 1, wherein the one or more auxiliary electrical connectors comprises between two and twelve electrical connectors.

3. The device of claim 1, wherein the one or more auxiliary electrical connectors comprises between two and six auxiliary electrical connectors.

4. The device of claim 1, wherein the data collection and control module of the main circuit board assembly comprises one or more microprocessors.

5. The device of claim 4, wherein the one or more microprocessors is operably connected to, through the one or more auxiliary electrical connectors, the auxiliary power sensor of each of the one or more auxiliary circuit board assemblies to receive information indicative of the at least one electrical characteristic from the auxiliary power sensor.

6. The device of claim 5, wherein the one or more microprocessors is operably connected to, through the one or more auxiliary electrical connectors, the auxiliary relay of each of the one or more auxiliary circuit board assemblies to control an open or closed state of the auxiliary relay.

7. The device of claim 1, wherein each of the one or more auxiliary circuit board assemblies further comprises an analog-to-digital converter to convert analog data from the auxiliary power sensor to digital data.

8. The device of claim 1, wherein the one or more auxiliary electrical connectors comprises one or more auxiliary ribbon cable connectors.

9. The device of claim 1, wherein the main circuit board assembly further comprises a main power sensor configured to sense at least one electrical power characteristic of a main power line for transmitting power to a disconnect panel.

10. The device of claim 9, wherein each of the auxiliary power sensor and the main power sensor comprises an electrical current sensor.

11. The device of claim 1, wherein the data collection and control module comprises a communication module for communicating information based on the at least one electrical power characteristic of the auxiliary power line to a user device.

12. The device of claim 1, wherein the auxiliary device comprises one or more of:
an electric vehicle charging station;
an electric vehicle;
a pump;
an air conditioning unit;
a heater; or
a refrigerator.

13. An electrical power monitoring device, comprising:
a main circuit board assembly, comprising:
one or more auxiliary electrical connectors; and
one or more auxiliary circuit board assemblies respectively connected to the one or more auxiliary electrical connectors, each of the one or more auxiliary circuit board assemblies comprising:
an auxiliary relay configured to open or close an auxiliary power line for powering an auxiliary device;
an auxiliary power sensor configured to sense at least one electrical power characteristic of the auxiliary power line; and
an auxiliary data collection and control module operably connected to the auxiliary power sensor for collecting and processing data from the auxiliary power sensor.

14. The device of claim 13, wherein the one or more auxiliary electrical connectors comprises two or more auxiliary electrical connectors.

15. The device of claim 13, wherein the main circuit board assembly further comprises a main power sensor configured to sense at least one electrical power characteristic of a main power line for transmission of power to a disconnect panel.

16. The device of claim 15, wherein the main circuit board assembly further comprises a main data collection and control module operably connected to the main power sensor for collecting and processing data from the main power sensor.

17. The device of claim 13, wherein each auxiliary data collection and control module comprises an auxiliary microprocessor.

18. The device of claim 13, wherein each auxiliary power sensor comprises an electrical current sensor.

19. A method of forming an electrical monitoring device, the method comprising:
operably coupling an auxiliary relay and an auxiliary sensor to an auxiliary circuit board to form an auxiliary circuit board assembly, the auxiliary relay configured to open or close an auxiliary power line for powering an auxiliary device and the auxiliary sensor configured to sense at least one electrical characteristic of the auxiliary power line;
operably coupling the auxiliary circuit board assembly to an auxiliary electrical connector of two or more auxiliary electrical connectors of a main circuit board assembly; and
operably coupling the auxiliary sensor to a data collection and control module.

20. The method of claim 19, wherein operably coupling the auxiliary sensor to the data collection and control module comprises at least one of:
operably coupling the auxiliary sensor to a main microprocessor of the main circuit board assembly; or
operably coupling the auxiliary sensor to an auxiliary microprocessor of the auxiliary circuit board assembly.
